(19) United States
(12) Patent Application Publication
(10) Pub. No.: US 2024/0157481 A1
(43) Pub. Date: May 16, 2024

(54) SEMICONDUCTOR CHIP SPLITTING METHOD USING A LASER AND SEMICONDUCTOR CHIP SPLIT BY THE SAME

(71) Applicant: SAMSUNG ELECTRONICS CO., LTD., Suwon-si (KR)

(72) Inventors: YEONGKWON KO, Suwon-si (KR); Soyeon KWON, Suwon-si (KR); Chungsun LEE, Suwon-si (KR); Jihun JUNG, Suwon-si (KR)

(73) Assignee: SAMSUNG ELECTRONICS CO., LTD., Suwon-si (KR)

(21) Appl. No.: 18/233,486

(22) Filed: Aug. 14, 2023

(30) Foreign Application Priority Data
Nov. 11, 2022 (KR) 10-2022-0151011

(51) Int. Cl. B23K 26/38; B23K 26/40; H01L 21/304; H01L 21/3065; H01L 21/683

(52) U.S. Cl. CPC B23K 26/38; B23K 26/40; H01L 21/3043; H01L 21/3065; H01L 21/6836; B23K 2101/40

(57) ABSTRACT

A semiconductor chip splitting method using a laser includes: performing a back-end-of-line (BEOL) process comprising forming wiring at or above a front surface of a semiconductor substrate; forming a lower trench at a rear surface of the semiconductor substrate; forming a laser scribing line on the semiconductor substrate along a region overlapping the lower trench; and splitting the semiconductor substrate into chips by a process comprising cutting along the laser scribing line.

### CROSS-REFERENCE TO RELATED APPLICATION

This application claims priority to Korean Patent Application No. 10-2022-0151011, filed on Nov. 11, 2022, in the Korean Intellectual Property Office, the disclosure of which is incorporated by reference herein in its entirety.

### BACKGROUND

### 1. Field

The disclosure relates to a semiconductor chip splitting method using a laser and a semiconductor chip split by the laser, and more particularly, to a semiconductor chip splitting method using stealth laser scribing and a semiconductor chip split by stealth laser scribing.

### 2. Description of Related Art

A method of cutting in a chip unit a wafer at which an active region and a circuit device such as wiring or the like are formed includes a mechanical cutting method using a dicing saw having a diamond tip, a scriber, or the like, and a method using a laser.

The dicing saw refers to a cutting device that rotates a disc-shaped blade equipped with the diamond tip to completely cut the wafer or form a wide groove corresponding to a width of the blade. On the other hand, a scriber refers to a device for forming a scribe line having a very thin width and a predetermined depth on the wafer by a reciprocating linear motion of a diamond tip. However, the mechanical cutting method is prone to chipping or cracking on a cut surface, and it is difficult to ensure a precise cutting process.

A method using a laser irradiates a laser to partially modify a physical property inside a semiconductor substrate, and uses the modified portion as a scribing line and applies a physical force to both sides of the scribing line to perform a cutting process. Even in the method using the laser, a crack may be non-uniformly formed due to non-uniformity of the modified portion, or the crack may propagate into a semiconductor chip.

### SUMMARY

One or more example embodiments provide a method of splitting a semiconductor chip using a laser and may improve reliability and help to prevent an unnecessary surplus from being left in a split semiconductor chip.

According to an aspect of an example embodiment, a semiconductor chip splitting method using a laser includes: performing a back-end-of-line (BEOL) process comprising forming wiring at or above a front surface of a semiconductor substrate; forming a lower trench at a rear surface of the semiconductor substrate; forming a laser scribing line on the semiconductor substrate along a region overlapping the lower trench; and splitting the semiconductor substrate into chips by a process comprising cutting along the laser scribing line.

According to an aspect of an example embodiment, a semiconductor chip includes: a semiconductor substrate; a plurality of wiring layers at or above a front surface of the semiconductor substrate; a plurality of interlayer insulating films disposed between the plurality of wiring layers; and a plurality of gap fill insulating films disposed at or above the plurality of interlayer insulating films, wherein a lower notch is formed along a lower corner of the semiconductor substrate and a cross-section of a reformed portion is exposed at a side surface of the semiconductor substrate.

### BRIEF DESCRIPTION OF DRAWINGS

The above and other aspects and features will be more apparent from the following description of example embodiments, taken in conjunction with the accompanying drawings, in which:

FIG. 1 is an arrangement diagram of a scribing line formed by applying a semiconductor chip splitting method using a laser according to an embodiment.

FIG. 2 is a cross-sectional view along line II-II of FIG. 1.

FIG. 3 is a cross-sectional view of a semiconductor chip split by the semiconductor chip splitting method using the laser according to an embodiment.

FIG. 4 is a process flowchart of the semiconductor chip splitting method using the laser according to an embodiment.

### DETAILED DESCRIPTION

Example embodiments will be described more fully with reference to the accompanying drawings, in which example embodiments are shown.

Embodiments described herein are provided as examples, and thus, the present disclosure is not limited thereto, and may be realized in various other forms. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

The drawings and descriptions are to be regarded as illustrative in nature and not restrictive. Throughout the specification, the same reference numerals refer to the same constituent elements.

It will be understood that although the terms “first” and “second” are used to describe various elements, these elements should not be limited by these terms. These terms are only used to distinguish one element of information from another. For example, without departing from the scope of the present disclosure, first constituent elements may be termed as second constituent elements; and similarly, second constituent elements may also be termed as first constituent elements.

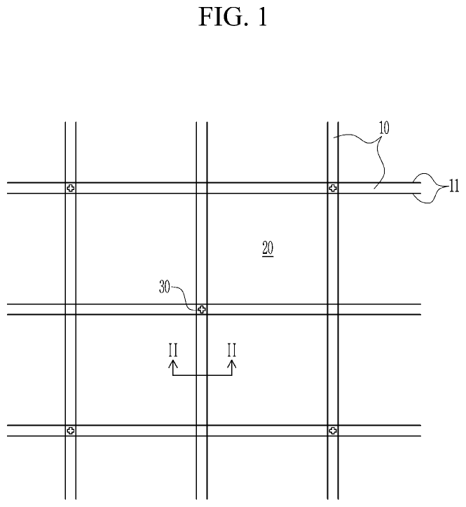

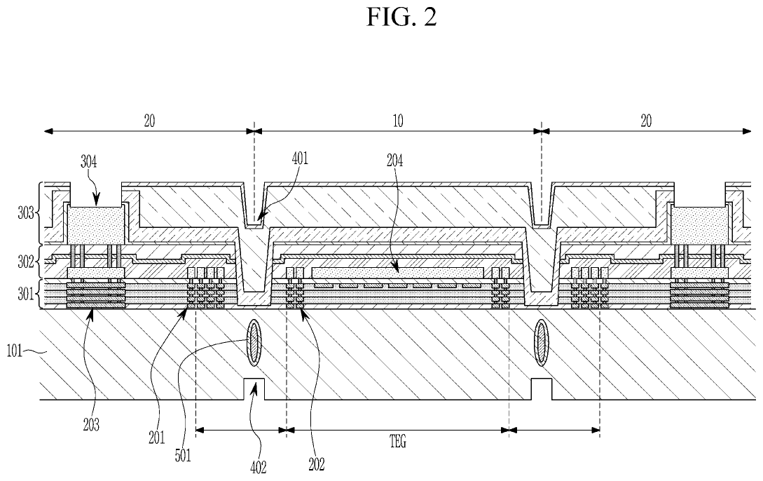

FIG. 1 is an arrangement diagram of a scribing line formed by applying a semiconductor chip splitting method using a laser according to an embodiment, and FIG. 2 is a cross-sectional view along line II-II of FIG. 1.

Referring to FIG. 1, semiconductor chip regions 20 may be disposed in a matrix at a wafer, and split regions 10 may be formed between the semiconductor chip regions 20 and may be extended in horizontal and vertical directions. The semiconductor chip regions 20 may be active regions in which various circuit devices such as transistors and the like and wirings are formed. Although the semiconductor chip regions 20 are shown in FIG. 1 as having a quadrangle shape and arranged in a matrix, a shape of the semiconductor chip region 20 is not limited to a quadrangle, and the arrangement is not limited to the matrix. The split regions 10 are also shown in strip shapes extending in straight lines in horizontal and vertical directions, but embodiments are not limited thereto, and various modifications such as a bent shape and the like are possible depending on a shape and arrangement of the semiconductor chip region 20. The split region 10 may form boundaries with the semiconductor chip region 20 by scribing lines 11, and a test element group (TEG) and an align key 30 may be disposed at the split region 10. The align key 30 may be disposed at a position where a horizontally split region 10 and a vertically split region 10 intersect.

Referring to FIG. 2, a circuit device such as a transistor or the like may be formed on a semiconductor substrate 101. The semiconductor substrate may include a material such as silicon or the like, and chip wiring 203 and a chip dam 201 made of a metal, a test element group (TEG) dam 202 and test element group (TEG) wiring 204 made of a metal, and the like may be formed above or at, including on, the semiconductor substrate. Each of the chip wiring 203, the chip dam 201, the TEG dam 202, and the TEG wiring 204 may be formed of a plurality of layers, and a low dielectric constant insulating film 301 may be disposed between the plurality of layers to provide insulation between metal wirings. The low dielectric constant insulating film 301 may be a kind of interlayer insulating film. For example, the low dielectric constant insulating film 301 may be a plurality of thin films made of a dielectric having a lower dielectric constant than silicon dioxide (SiO₂).

The chip wiring 203 may be wiring that connects circuit devices formed at the semiconductor substrate 101 or connects the circuit devices to the outside. The TEG wiring 204 may be wiring formed for testing, monitoring, or the like of a semiconductor chip. The chip dam 201 and the TEG dam 202 may be structures that prevent a crack from propagating to the semiconductor chip region when the semiconductor chip is split through scribing and that strengthen around the scribing line so that the semiconductor chip is split along the scribing line. The chip dam 201 and the TEG dam 202 may be formed together when the chip wiring 203 and the TEG wiring 204 are formed.

An interlayer insulating film 302 may be disposed above or at, including on, the chip wiring 203, the chip dam 201, the TEG dam 202, the TEG wiring 204, and the low dielectric constant insulating film 301. The interlayer insulating film 302 may include a plurality of thin films for insulating between metal wiring layers such as a chip contact portion 304 or the like disposed above or at, including on, the low dielectric constant insulating film 301, and may include thin films in which a silicon nitride (SiNₓ) and/or a silicon oxide (SiOₓ) are repeatedly stacked.

A gap fill insulating film 303 may be disposed above or at, including on, the interlayer insulating film 302. The gap fill insulating film 303 may include films in which a silicon nitride (SiNₓ) and a silicon oxide (SiOₓ) such as a tetraethoxysilane (TEOS) or the like are repeatedly stacked. The gap fill insulating film 303 may include a plurality of insulating films in which the gap fill insulating film is stacked after photo-etching and removing the low dielectric constant insulating film 301 and the interlayer insulating film 302 between the chip dam 201 and the TEG dam 202, so that an insulating film gap formed at an upper portion of a region between the chip dam 201 and the TEG dam 202 is filled and an upper trench 401 is formed. The upper trench 401 may be a trench naturally formed while the gap fill insulating film 303 fills the insulating film gap formed by removing the low dielectric constant insulating film 301 and the interlayer insulating film 302.

A lower trench 402 may be formed at a lower portion of the semiconductor substrate 101. The lower trench 402 may overlap the upper trench 401 in a vertical direction, and may be formed together in a process of forming the align key 30. That is, the lower trench 402 may be formed together when the align key 30 is formed at a lower surface of the semiconductor substrate 101 in order to accurately align the semiconductor substrate 101 in a subsequent process after a back-end-of-line (BEOL) process, so that the lower trench 402 may be formed without adding a separate process. Instead of forming the lower trench 402 together with the align key 30, the lower trench 402 may be formed together in another process of photo-etching a lower surface of the semiconductor substrate 101 such as a photo-etching process for forming a through silicon via (TSV) exposed region or the like. In addition, the lower trench 402 may be formed through a physical method such as laser irradiation or the like, a mechanical method using a blade or a saw, or a chemical method such as wet etching, dry etching, or the like, and a separate process may be added to form the lower trench 402. In various embodiments, the lower trench 402 may be formed with various cross-sectional shapes or structures such as a curved cross-section (e.g., a semicircle cross-section, a semi-ellipse cross-section, or the like), a triangular cross-section, or a pentagonal cross-section in addition to a rectangular (or quadrangular) cross-section, and combinations thereof.

A reformed portion 501 may be formed inside the semiconductor substrate 101 by laser irradiation. The reformed portion 501 may be a portion in which a portion of the semiconductor substrate 101 that is a single crystal is phase-transformed into a polycrystalline portion or an amorphous portion by the laser irradiation. A void generated during the phase transformation process may exist at the reformed portion 501. The reformed portion 501 may be formed at a position overlapping the upper trench 401 and the lower trench 402. For example, as shown in the embodiment of FIG. 2, the reformed portion 501 may be generally aligned with the upper trench 401 and the lower trench 402 in a vertical direction.

As described above, when the lower trench 402 is formed, the lower trench 402 may form the scribing line together with the upper trench 401 and the reformed portion 501 so that a splitting property of the scribing line is improved. Thus, when the semiconductor chip is split, the crack may be prevented from propagating to the semiconductor chip region beyond the scribing line, and a fragment of the split region 10 may be prevented from remaining by adhering to the semiconductor chip region 20 due to non-uniform generation of the crack. Therefore, when the chip split by the semiconductor chip splitting method according to the embodiment is bonded by applying hybrid compression bonding (HCB) in which a pad and a solder ball are omitted during a bonding of chips, there may be few defects caused by a remaining TEG pattern or the like.

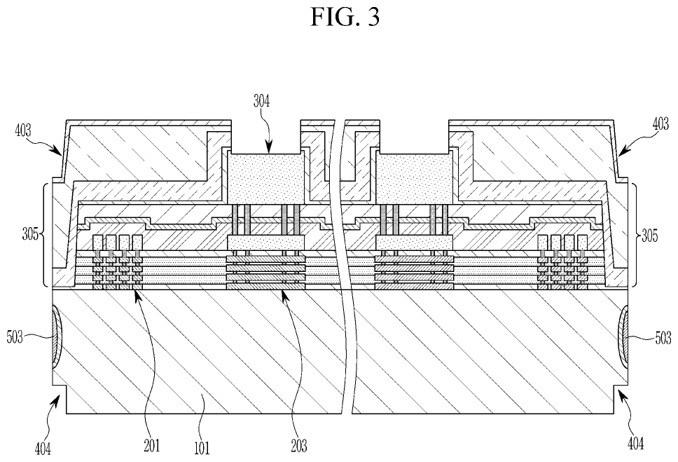

FIG. 3 is a cross-sectional view of the semiconductor chip split by the semiconductor chip splitting method using the laser according to an embodiment.

A side surface of the semiconductor chip split through the semiconductor chip splitting method according to the embodiment may have an upper notch 403 and a lower notch 404. The upper notch 403 may be a trace of the upper trench 401, and the lower notch 404 may be a trace of the lower trench 402. Accordingly, the upper notch 403 may have a shape in which the gap fill insulating film 303 at an upper side of the semiconductor chip is recessed toward a central portion of the semiconductor chip, and the lower notch 404 has a shape in which a lower portion of a side surface of the semiconductor chip is recessed toward a central portion of the semiconductor chip. An uppermost film of the gap fill insulating film 303 may be exposed at the upper notch 403, and the semiconductor substrate 101 may have a shape in which a lower corner of the semiconductor substrate 101 is recessed. The lower notch 404 may have various cross-sections depending on a cross-sectional shape of the lower trench 402. For example, according to embodiments, if the lower trench 402 has a quadrangular cross-section, the lower notch 404 may have an L-shaped cross-section as shown in FIG. 3, if the lower trench has a triangular cross-section, the lower notch may have a simple inclined surface, and if the lower trench has a semicircular cross-section, the lower notch may have an arcuate cross-section.

A cross-section 503 of the reformed portion may be exposed at a side surface of the semiconductor substrate 101. The cross-section 503 of the reformed portion may be a polycrystalline portion or an amorphous portion and may include a trace of a void. The trace of the void may be a fine groove. The cross-section 503 of the reformed portion may be separated from the lower notch 404 and a single crystal portion may exist between the cross-section 503 of the reformed portion and the lower notch 404, or the cross-section 503 of the reformed portion may extend to the lower notch 404.

A cross-section 305 of the gap fill insulating film may be exposed below the upper notch 403.

As described above, the upper notch 403, the lower notch 404, and the cross-section 503 of the reformed portion may be disposed at a side surface of the semiconductor chip split by the semiconductor chip splitting method using the laser according to the embodiment, so that whether the semiconductor chip splitting method using the laser according to the embodiment is used may be determined.

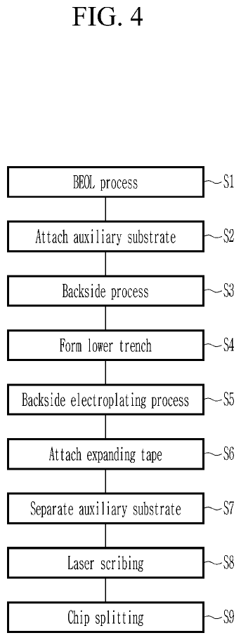

FIG. 4 is a process flowchart of the semiconductor chip splitting method using the laser according to an embodiment.

Splitting of the semiconductor chip using the laser according to the embodiment may include using a BEOL process (S1) of forming the upper trench 401, a lower trench formation process (S4), a laser scribing process (S8), and the like.

More specifically, referring to FIGS. 2 and 4, the chip wiring 203 and the TEG wiring 204 may be formed above or at, including on, the semiconductor substrate 101, and the BEOL process forming the interlayer insulating film 302 and the gap fill insulating film 303 may be performed (S1). The gap fill insulating film 303 may include a plurality of insulating films in which the gap fill insulating film is stacked after selectively etching and removing the low dielectric constant insulating film 301 and the interlayer insulating film 302 between the chip dam 201 and the TEG dam 202 so that an insulating film gap formed at an upper portion of a region between the chip dam 201 and the TEG dam 202 is filled and an upper trench 401 is formed. The upper trench 401 may be a trench naturally formed while the gap fill insulating film 303 fills the insulating film gap formed by removing the low dielectric constant insulating film 301 and the interlayer insulating film 302.

Next, an auxiliary substrate (not shown) may be attached above or at, including on, the gap fill insulating film 303 (S2). The auxiliary substrate may be a temporary structure that supplements strength of the wafer and facilitates handling of the wafer when a backside process of processing a lower portion of the semiconductor substrate 101 is performed.

Next, the backside process (or a rear surface process) for a lower portion of the semiconductor substrate 101 may be performed (S3). The backside process may be an etching process for reducing a thickness of the semiconductor substrate 101 or a process for forming a structure such as a through silicon via (TSV) or the like at the semiconductor substrate 101.

Next, the lower trench 402 may be formed at a rear surface (a lower surface in FIG. 2) of the semiconductor substrate 101 through photolithography (S4). The lower trench 402 may be formed together with the align key 30 or the lower trench 402 may be formed together in another process of photo-etching a rear surface of the semiconductor substrate 101 such as a photo-etching process for forming a through silicon via (TSV) exposed region or the like. In addition, the lower trench 402 may be formed through a physical method such as laser irradiation or the like, a mechanical method using a blade or a saw, or a chemical method such as wet etching, dry etching, or the like, and a separate process may be added to form the lower trench 402.

Next, a backside electroplating process (a rear surface electroplating process) may be performed to form a metal pattern such as a contact pad or the like at the rear surface of the semiconductor substrate 101 (S5). The process may be a process of forming a metal structure to promote electrical connection between chips when the rear surface of the semiconductor substrate 101 is bonded to another chip through a method such as hybrid compression bonding (HCB) or the like.

Next, an expanding tape may be attached to the rear surface of the semiconductor substrate 101 (S6).

Next, the auxiliary substrate may be separated (S7).

Next, the scribing line may be formed by irradiating a stealth laser through the upper trench 401 to form the reformed portion 501 in the semiconductor substrate 101 (S8). Here, a stealth laser refers to a laser that passes through the gap fill insulating film and generates thermal energy inside the semiconductor substrate 101.

Next, each semiconductor chip may be split by freezing the wafer including the semiconductor substrate 101 and splitting the wafer along the scribing line by stretching the expanding tape in one or more direction up to all possible directions (S9). In this case, the lower trench 402 may assist the reformed portion 501 to improve a splitting property of the scribing line so that the crack is uniformly generated, and the crack may be prevented from being propagated into the semiconductor chip or a TEG portion may be prevented from being left in the split semiconductor chip without being completely separated.

While aspects of example embodiments have been particularly shown and described, it will be understood that various changes in form and details may be made therein without departing from the spirit and scope of the following claims.

What is claimed is:

1. A semiconductor chip splitting method using a laser, comprising:
performing a back-end-of-line (BEOL) process comprising forming wiring at or above a front surface of a semiconductor substrate;
forming a lower trench at a rear surface of the semiconductor substrate;
forming a laser scribing line on the semiconductor substrate along a region overlapping the lower trench; and
splitting the semiconductor substrate into chips by a process comprising cutting along the laser scribing line.

2. The semiconductor chip splitting method of claim 1, wherein, in the BEOL process, an upper trench is formed at a region overlapping the laser scribing line.

3. The semiconductor chip splitting method of claim 2, wherein the upper trench is formed by providing a gap fill insulating film after selectively etching and removing a region of a low dielectric constant insulating film and a region of an interlayer insulating film.

4. The semiconductor chip splitting method of claim 1, wherein the lower trench is formed in a process together with forming a structure at the rear surface of the semiconductor substrate.

5. The semiconductor chip splitting method of claim 4, wherein the lower trench is formed in a process together with forming an align key at the rear surface of the semiconductor substrate.

6. The semiconductor chip splitting method of claim 1, wherein the lower trench is formed by a process comprising at least one of a physical method, a mechanical method, and a chemical method performed at the rear surface of the semiconductor substrate.

7. The semiconductor chip splitting method of claim 6, wherein the lower trench is formed through a process comprising at least one of laser irradiation, cutting with a blade, cutting with a saw, wet etching or dry etching.

8. The semiconductor chip splitting method of claim 2, wherein the laser scribing line is formed by a process comprising irradiating the laser to the semiconductor substrate through the upper trench.

9. The semiconductor chip splitting method of claim 8, wherein the laser scribing line is in a region in which a portion of the semiconductor substrate is reformed by irradiation of the laser to be converted into a polycrystalline portion or an amorphous portion.

10. The semiconductor chip splitting method of claim 9, wherein the laser scribing line comprises two lines and forms a split region.

11. The semiconductor chip splitting method of claim 10, wherein a test element group (TEG) is disposed at the split region.

12. The semiconductor chip splitting method of claim 10, wherein a dam comprising a metal layer comprising the wiring is disposed at sides of the laser scribing line.

13. The semiconductor chip splitting method of claim 1, wherein the lower trench comprises a cross-sectional structure having at least one of a quadrangular shape, a triangular shape, a pentagonal shape, a semicircular shape, and a semielliptical shape.

14. The semiconductor chip splitting method of claim 1, further comprising:
attaching an auxiliary substrate to the front surface of the semiconductor substrate and performing a backside process of the semiconductor substrate between the BEOL process and the forming of the lower trench; and
forming a metal pattern at the rear surface of the semiconductor substrate, attaching an expanding tape to the rear surface of the semiconductor substrate, and separating the auxiliary substrate between the forming of the lower trench and the forming of the laser scribing line.

15. A semiconductor chip comprising:
a semiconductor substrate;
a plurality of wiring layers at or above a front surface of the semiconductor substrate;
a plurality of interlayer insulating films disposed between the plurality of wiring layers; and
a plurality of gap fill insulating films disposed at or above the plurality of interlayer insulating films,
wherein a lower notch is formed along a lower corner of the semiconductor substrate and a cross-section of a reformed portion is exposed at a side surface of the semiconductor substrate.

16. The semiconductor chip of claim 15, further comprising an upper notch along an upper corner of the plurality of gap fill insulating films.

17. The semiconductor chip of claim 16, wherein an uppermost layer of the plurality of gap fill insulating films is exposed at the upper notch.

18. The semiconductor chip of claim 15, wherein at least one of a polycrystalline portion and an amorphous portion is exposed at the cross-section of the reformed portion.

19. The semiconductor chip of claim 18, wherein the cross-section of the reformed portion comprises a trace of a void.

20. The semiconductor chip of claim 15, wherein the cross-section of the reformed portion is spaced apart from the lower notch and a single crystal portion is disposed between the cross-section of the reformed portion and the lower notch.
